(19) United States
(12) Patent Application Publication
(10) Pub. No.: US 2008/0079084 A1
(43) Pub. Date: Apr. 3, 2008

(54) Enhanced mobility MOSFET devices

(75) Inventor: Hussein I. Hanafi, Basking Ridge, NJ (US)

Correspondence Address: SCHWEGMAN, LUNDBERG & WOESSNER, P.A., P.O. BOX 2938, MINNEAPOLIS, MN, 55402, US

(73) Assignee: Micron Technology, Inc.

(21) Appl. No.: 11/528,836

(22) Filed: Sep. 28, 2006

(51) Int. Cl. H01L 29/78; H01L 21/8238

(52) U.S. Cl. 257/369; 257/616; 438/199; 438/275

(57) ABSTRACT

Semiconductor devices having enhanced mobility regions and methods of forming such devices are disclosed. In some embodiments, a method includes providing a SiGe layer on a supporting substrate, and forming isolation structures within the SiGe layer that define a first region and a second region. The conductivity of the SiGe layer in the second region may be altered to form a suitably doped well. A layer of strained Ge can be formed on the well, and a layer of strained Si may be formed on the surface of the first region. A layer of strained Si may be formed on the strained Ge layer. Source/drain regions may be formed in the well and in the first device region, and a dielectric layer may be formed on the Si layer. Gate structures may then be positioned on the dielectric layer.

### TECHNICAL FIELD

The information disclosed herein relates generally to integrated circuit devices and fabrication methods, including semiconductor devices having enhanced mobility regions and methods of forming such devices.

### BACKGROUND

The incorporation of increasing numbers of MOS transistor devices into progressively smaller integrated circuits remains an important challenge in Very Large Scale Integration (VLSI). For example, the implementation of complementary metal-oxide semiconductor (CMOS) logic typically includes a plurality of both p-channel metal-oxide semiconductor field-effect transistor (p-MOSFET) and n-MOSFET devices that constitute logic gates, which may be found in a variety of digital devices employed in computers, telecommunications and signal processing equipment. To date, aggressive dimensional reductions in the geometry of MOSFET devices have been achieved through the application of various scaling relationships to the MOSFET device. Briefly, and in general terms, many of the known MOSFET scaling relationships are predicated upon the assumption that electrical fields within the device are maintained constant within the device as the relative dimensions of the MOSFET device are reduced. Accordingly, the application of scaling laws to MOSFETs has resulted in significant physical size reductions by reducing the gate/channel length, reductions in the thickness of the gate dielectric layer, as well as other specific device alterations, such as selectively increasing doping levels in the channel region.

As the dimensions of MOSFET devices are reduced still further, however, other physical phenomena have become increasingly important in device behavior, which are not readily addressed by scaling. For example, as devices are scaled below the 90 nanometer (nm) node, channel lengths in MOSFETs are generally smaller than about 50 nm, thus exacerbating the short channel effect. Device doping concentrations have correspondingly increased in certain MOSFET devices in an attempt to address the short channel effect. High doping concentrations (in excess of about 3×10¹⁸/cm³) have nevertheless adversely affected channel carrier mobility, as well as generally lowering the turn-on current for the device.

One method for overcoming reduced channel carrier mobility in MOSFET devices involves the use of strained semiconductor materials. In general, it has been established that subjecting a selected semiconductor material to a tensile strain induces an electron mobility enhancement, while subjecting another selected semiconductor material to a compressive strain correspondingly induces a hole mobility enhancement. Suitable semiconductor materials for strained applications generally include silicon (Si) and selected alloys of silicon and germanium (SiGe) that are configured in layers within the device. Accordingly, relative differences in the lattice spacing of the Si and the Si Ge alloy can promote a strained state in a selected portion of the device. For example, in one approach, a strained layer of Si that is grown on a relaxed layer of Si₁₋ₓGeₓ (where x is a selected fractional value that is less than one) has been demonstrated to improve n-MOSFET performance. In another approach, compressively strained Ge grown upon relaxed Si₁₋ₓGeₓ and capped with strained Si has also been demonstrated to generate heterostructures that improve the performance of p-MOSFET devices.

Although the foregoing strained semiconductor structures constitute improvements in the state of the art, the two approaches are not readily fabricated in a unitary structure, so that the fabrication of integrated devices having CMOS logic (which generally includes p-MOSFET and n-MOSFET devices) is not generally possible. Therefore, what is needed in the art are methods and structures that permit p-MOSFET and n-MOSFET devices to be efficiently and economically included in a unitary structure.

### BRIEF DESCRIPTION OF THE DRAWINGS

The various embodiments of the present invention are described in detail below with reference to the following drawings.

FIG. 1 is a partial cross sectional view that will be used to describe a method of forming a semiconductor device according to various embodiments of the invention.

FIG. 2 is another partial cross sectional view that will be used to describe a method of forming a semiconductor device according to various embodiments of the invention.

FIG. 3 is still another partial cross sectional view that will be used to describe a method of forming a semiconductor device according to various embodiments of the invention.

FIG. 4 is still yet another partial cross sectional view that will be used to describe a method of forming a semiconductor device according to various embodiments of the invention.

FIG. 5 is another partial cross sectional view that will be used to describe a method of forming a semiconductor device according to various embodiments of the invention.

FIG. 6 is still another partial cross sectional view that will be used to describe a method of forming a semiconductor device according to various embodiments of the invention.

FIG. 7 is yet another partial cross sectional view that will be used to describe a method of forming a semiconductor device according to various embodiments of the invention.

FIG. 8 is still yet another partial cross sectional view that will be used to describe a method of forming a semiconductor device according to various embodiments of the invention.

FIG. 9a is another partial cross sectional view that will be used to describe a method of forming a semiconductor device according to various embodiments of the invention.

FIG. 9b is still another partial cross sectional view that will be used to describe a method of forming a semiconductor device according to various embodiments of the invention.

FIG. 10 is yet another partial cross sectional view that will be used to describe a method of forming a semiconductor device according to various embodiments of the invention.

FIG. 11 is another partial cross sectional view that will be used to describe a method of forming a semiconductor device according to various embodiments of the invention.

FIG. 12 is a partial cross sectional view that will be used to describe a method of forming a semiconductor device according to various embodiments of the invention.

FIG. 13 is still another partial cross sectional view that will be used to describe a method of forming a semiconductor device according to various embodiments of the invention.

FIG. 14 is yet another partial cross sectional view that will be used to describe a method of forming a semiconductor device according to various embodiments of the invention.

FIG. 15 is still yet another partial cross sectional view that will be used to describe a method of forming a semiconductor device according to various embodiments of the invention.

FIG. 16 is another partial cross sectional view that will be used to describe a method of forming a semiconductor device according to various embodiments of the invention.

FIG. 17 is yet another partial cross sectional view that will be used to describe a method of forming a semiconductor device according to various embodiments of the invention.

FIG. 18 is still another partial cross sectional view that will be used to describe a method of forming a semiconductor device according to various embodiments of the invention.

FIG. 19 is still yet another partial cross sectional view that will be used to describe a method of forming a semiconductor device according to various embodiments of the invention.

FIG. 20 is another partial cross sectional view that will be used to describe a method of forming a semiconductor device according to various embodiments of the invention.

FIG. 21 is still another partial cross sectional view that will be used to describe a method of forming a semiconductor device according to various embodiments of the invention.

FIG. 22a is yet another partial cross sectional view that will be used to describe a method of forming a semiconductor device according to various embodiments of the invention.

FIG. 22b is another partial cross sectional view that will be used to describe a method of forming a semiconductor device according to various embodiments of the invention.

FIG. 23 is still yet another partial cross sectional view that will be used to describe a method of forming a semiconductor device according to various embodiments of the invention.

FIG. 24 is a partial cross sectional view that will be used to describe a method of forming a semiconductor device according to various embodiments of the invention.

FIG. 25 is still another partial cross sectional view that will be used to describe a method of forming a semiconductor device according to various embodiments of the invention.

FIG. 26 is a diagrammatic block view of a processing system according to another embodiment of the invention.

### DETAILED DESCRIPTION

Many of the various embodiments disclosed relate to semiconductor devices having enhanced mobility regions and methods of forming such devices. Specific details of several embodiments of the invention are set forth in the following description and in FIGS. 1 through 25 to provide a thorough understanding of such embodiments. One skilled in the art, however, will understand that additional embodiments are possible, and that many embodiments may be practiced without several of the details described in the following description.

FIG. 1 is a partial cross sectional view that will be used to describe a method of forming a semiconductor device 10 according to various embodiments of the invention. The semiconductor device 10 may include a carrier substrate 12, which may further include a silicon-germanium (SiGe) layer 14 that may be epitaxially grown on the carrier substrate 12 to a desired thickness. In general, a mechanical strain is developed between the SiGe layer 14 and the carrier substrate 12 at an interface layer 16 by different inter-atomic distances present in the respective materials. The SiGe layer 14 may comprise an alloy of Silicon and Germanium according to the general formula Si₁₋ₓGeₓ, where x may range between approximately 0.5 and 0.6. Typically, as the thickness of the SiGe layer 14 increases, the mechanical strain gradually decreases, so that when the desired thickness of the SiGe layer 14 is achieved, the SiGe layer 14 generally includes a relatively unstrained surface layer 18. A device substrate 20 may comprise a bulk silicon substrate, or a silicon-on-insulator (SOI) structure, such as a silicon-on-sapphire (SOS) substrate.

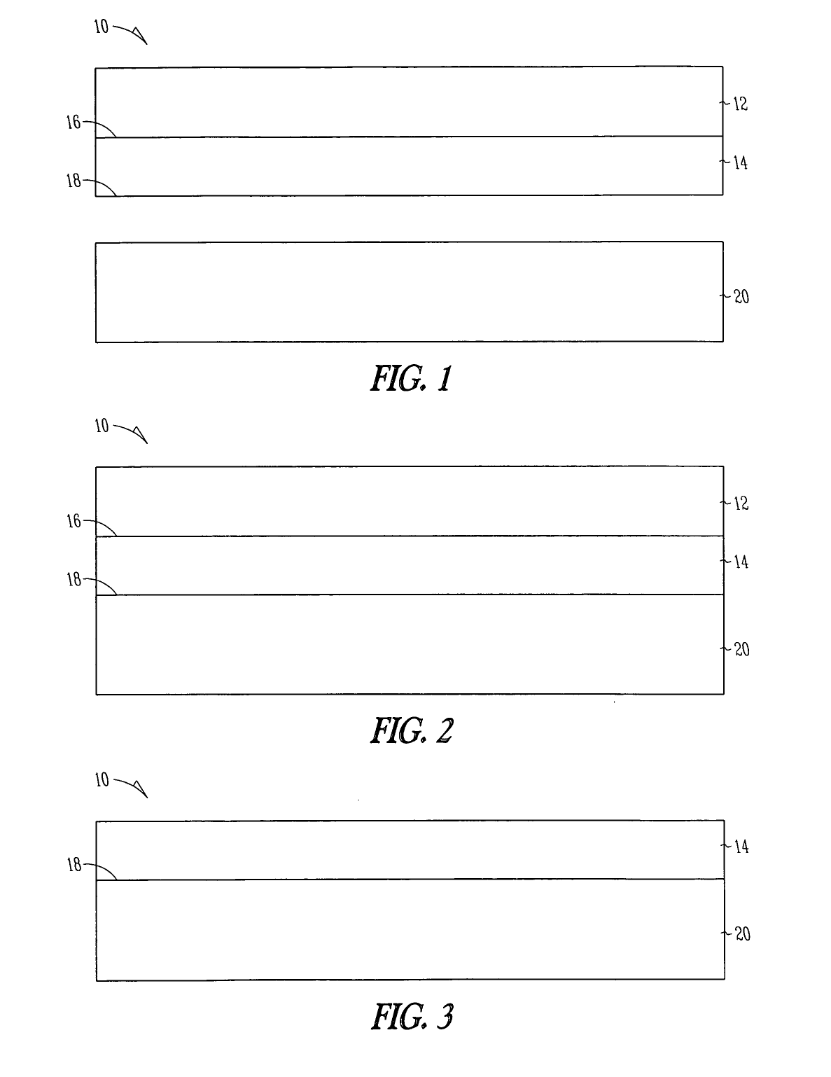

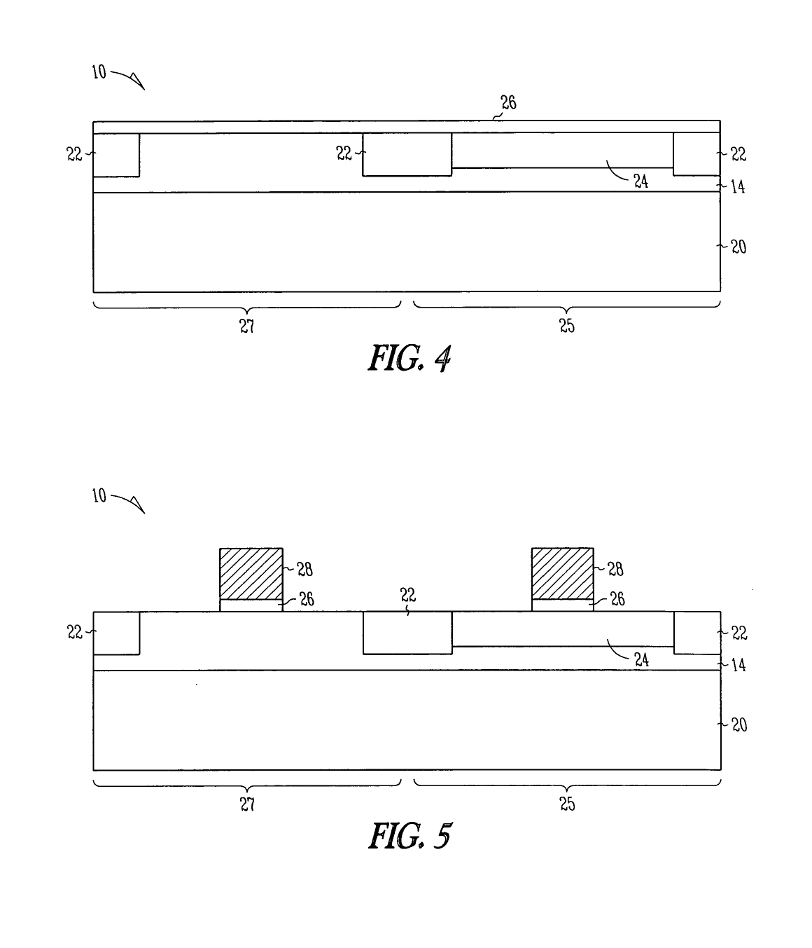

Referring now to FIG. 2, the surface layer 18 of the SiGe layer 14 may be bonded to the device substrate 20 using a suitable adhesive material, such as benzocyclobutene (BCB), although other adhesive compounds may be used. The carrier substrate 12 may then be thinned by grinding, planarization, or other known wafer thinning methods so that the portion of carrier substrate 12 not including the SiGe layer 14 is substantially removed (not shown in FIG. 2). In addition, portions of the SiGe layer 14 may also be removed in order to eliminate undesired strained regions within the SiGe layer 14 that are proximate to the interface layer 16. As a result, a relatively unstrained SiGe layer 14 may be coupled to the device substrate 20, as shown in FIG. 3. Alternately, in some embodiments, the SiGe layer 14 may be epitaxially grown on the device substrate 20 so that the foregoing wafer bonding and wafer thinning processes are avoided.

Referring now to FIG. 4, shallow trench isolation (STI) structures 22 may be formed in the SiGe layer 14. Briefly, and in general terms, the STI structures 22 may be formed by applying known photolithographic procedures. For example, a photoresist material (not shown in FIG. 4) may be applied to an upper surface of the SiGe layer 14, and exposed through a suitable mask. The exposed photoresist may be developed to establish openings through the photoresist material at selected locations for the STI structures 22. The selected locations may then be etched to form trenches extending into the SiGe layer 14 using a suitable anisotropic etching process. The trenches thus formed may be filled with a deposited dielectric material, such as silicon dioxide, or other known dielectric materials to form the STI structures 22.

Still referring to FIG. 4, an n-doped well 24 may be formed in the SiGe layer 14 so that a p-MOS region may be defined in the semiconductor device 10. Correspondingly, an adjacent n-MOS region 27 may also be defined. The n-doped well 24 may be formed using a suitable doping method, such as ion implantation, or other known doping methods. Prior to the implantation process, however, a suitable layer (also not shown in FIG. 4) may be applied to the device 10 that is patterned to provide an opening at the desired implant location. One suitable layer is a silicon nitride layer that may be stripped from the device 10 following the doping procedure. An annealing process may also be optionally applied to the device 10 to minimize the adverse effects of the ion implantation procedure. A pad dielectric layer 26 may then be applied to the device 10 that may include, for example, an oxide layer.

FIG. 5 shows a pair of dummy gate structures 28 formed on the device 10 by depositing a polysilicon layer (not shown in FIG. 5) on the pad dielectric layer 26 to a desired thickness. The polysilicon layer may be deposited using chemical vapor deposition (CVD), or other known deposition methods. The polysilicon layer is then suitably patterned using known photolithographic procedures, as previously described, and selectively removed from the device 10 to form the dummy gate structures 28 in the respective p-MOS region 25 and the n-MOS region 27. In some embodiments, the dummy gate structures 28 may be formed by reactive ion etching (RIE) the polysilicon layer, although other suitable methods may also be used. As further shown in FIG. 5, the pad dielectric layer 26 may be stripped from the device 10 so that the remaining portions of the pad dielectric layer 26 are positioned between the dummy gate structures 28 and a surface 30 of the device 10.

Turning now to FIG. 6, source/drain extensions 32 may be formed in the n-doped well 24 so that a channel region 33 is established between the source/drain extensions 32. Ion implantation of a selected chemical species may be employed to form the source/drain extensions 32, as is known in the art. The source/drain extensions 32 may also include halo implantation regions that advantageously minimize short channel effects in the p-MOS region 25. Correspondingly, source/drain extensions 36 may also be formed in the n-MOS region 27 to provide a channel region 37 between the source/drain extensions 36. The source/drain extensions 36 may be formed by ion implantation of a selected chemical species, which may also include halo implantation regions. Insulating spacers 40 may be formed on opposing sidewalls of each of the dummy gate structures 28 by selective material deposition and etching processes, which are known in the art. Although the insulating spacers 40 may be formed from any dielectric material, in the various embodiments, the insulating spacers 40 may comprise a nitride, an oxynitride, or any suitable combination of the foregoing dielectric materials.

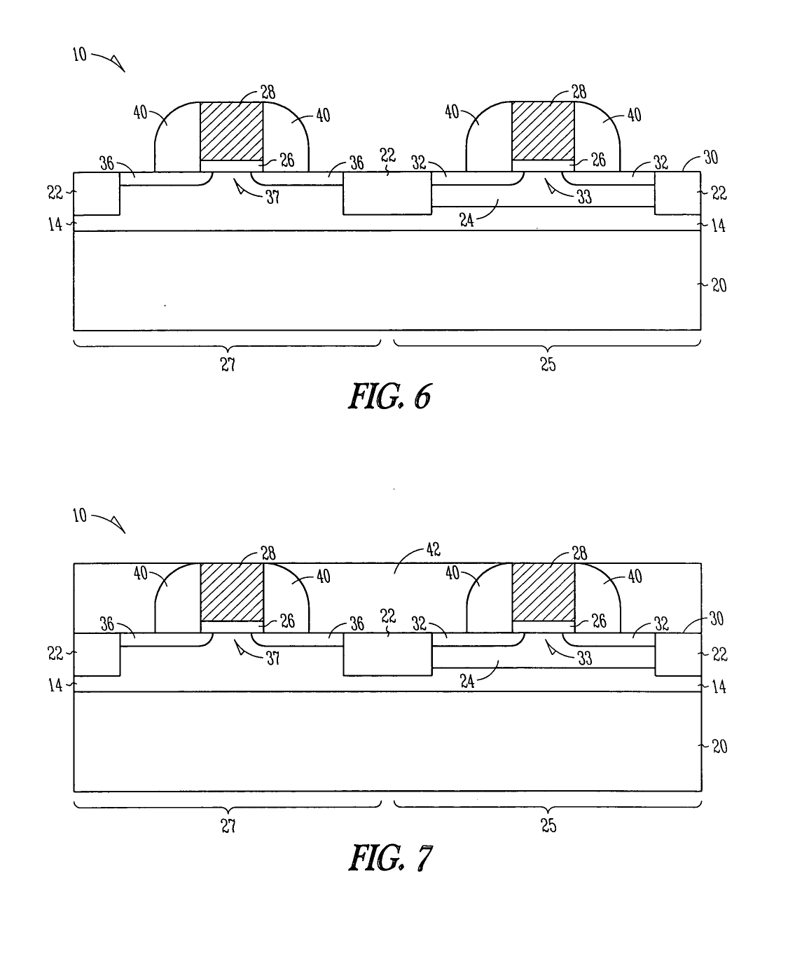

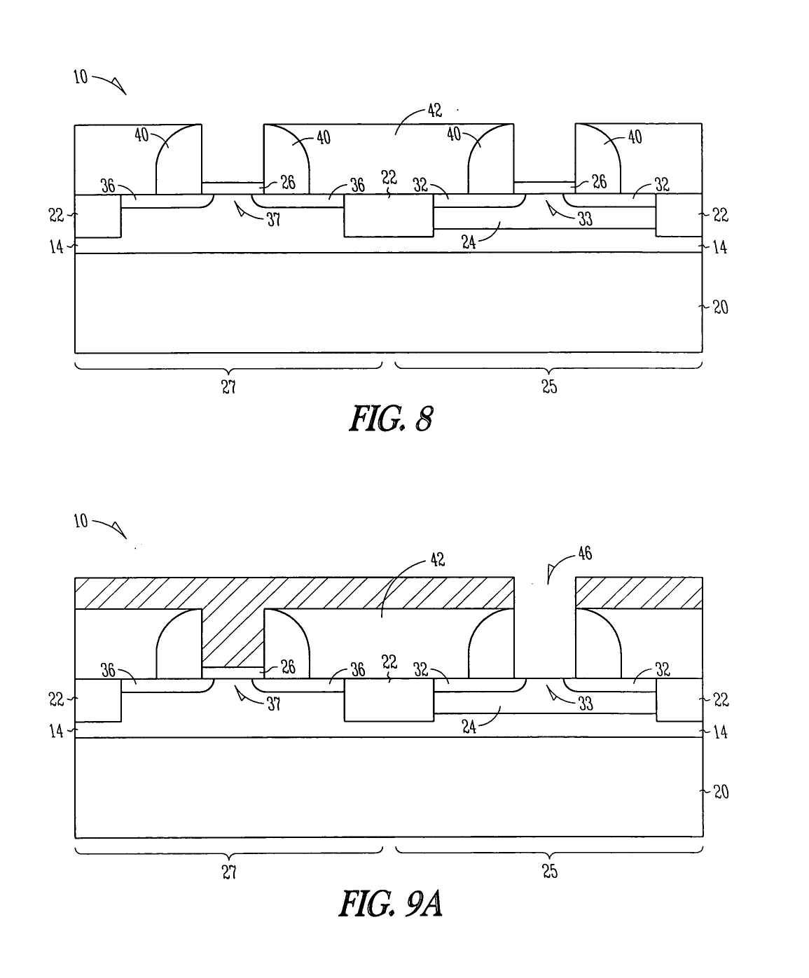

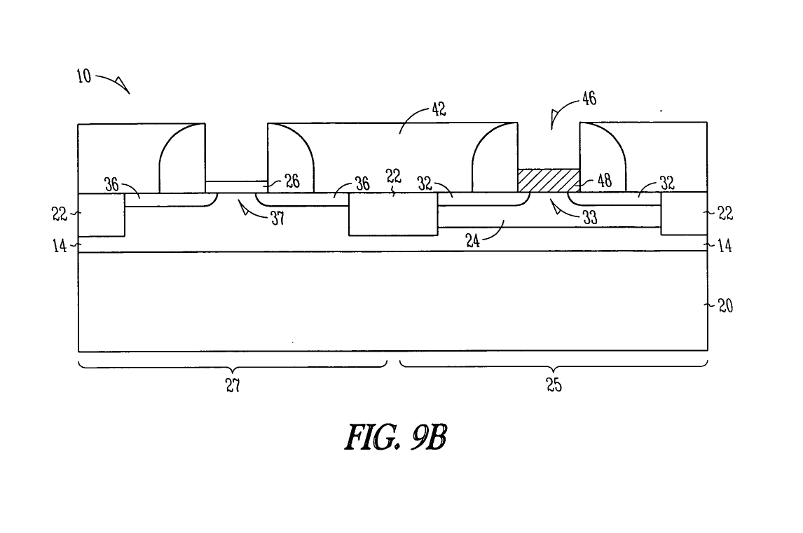

A conformal dielectric layer 42 may be applied to the device 10 that substantially cover the surface 30, and that further surround the dummy gate structures 28 and the insulating spacers 40, as shown in FIG. 7. The conformal dielectric layer 42 may include, for example, a silicon dioxide layer that is deposited on the device 10 using chemical vapor deposition (CVD). Following deposition of the conformal dielectric layer 42, the layer 42 may be planarized using chemical-mechanical planarization (CMP) so that a thickness of the layer 42 extends from the surface 30 to approximately a height of the dummy gate structures 28. Optionally, an endpointing layer may be included in the layer 42 so that the planarization procedure is stopped when the dummy gate structures 28 are exposed. Referring now also to FIG. 8, the dummy gate structures 28 for the p-MOS region 25 and the n-MOS region 27 may be selectively removed from the device 10. The dummy gate structures 28 may be removed by any suitable etch procedure that is relatively selective for polysilicon. For example, the dummy gate structures may be removed using a dry etch process, such as plasma etching that employs a suitable chemistry, although other dry etch methods may also be used.

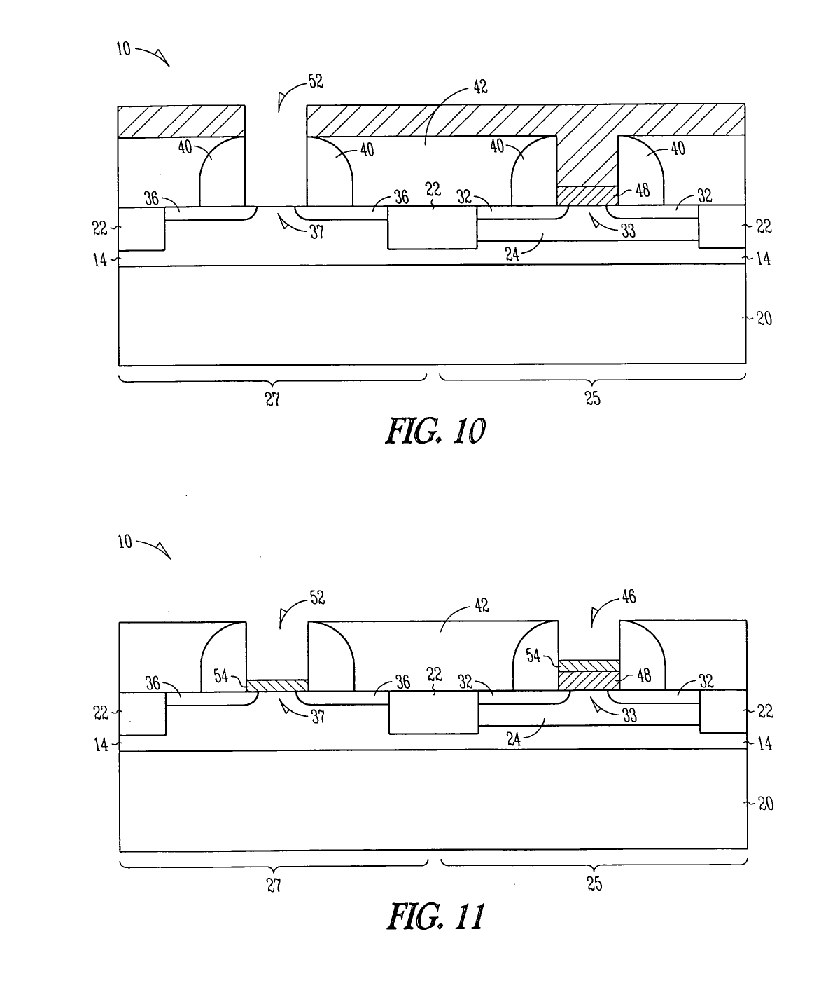

Turning now to FIG. 9a, a photoresist layer 44 may be applied to an exposed surface of the conformal dielectric layer 42, which may be locally removed from the p-MOS region 25 by photolithographic methods, so that a p-MOS recess 46 is defined. The pad dielectric layer 26 may then be removed from the p-MOS recess 46. The layer 26 may be removed, for example, by various dry etch procedures known in the art. The photoresist layer 44 may then be stripped from the conformal dielectric layer 42. A strained germanium (Ge) layer 48 may then be grown in the p-MOS recess 46, as shown in FIG. 9b. In the various embodiments, the strained Ge layer 48 may be epitaxially grown to a thickness of approximately 12 nanometers (nm), although the strained Ge layer 48 may have other thicknesses, which may be greater than the foregoing thickness, or even less than this thickness.

With reference now to FIG. 10, a photoresist layer 50 may again be applied to the exposed surface of the conformal dielectric layer 42, which may be locally stripped from the n-MOS region 27 to define an n-MOS recess 52. The pad dielectric layer 26 may then be removed from the n-MOS recess 52. With reference also now to FIG. 11, the photoresist layer 50 may then be stripped to expose the p-MOS recess 46. A strained silicon (Si) layer 54 may then be grown in the p-MOS recess 46 and the n-MOS recess 52. In the various embodiments, the strained Si layer 54 may be epitaxially grown to a thickness of approximately five nanometers (nm), although the strained Si layer 54 may have other thicknesses, which may be greater or even less than the foregoing thickness.

Referring now to FIG. 12, a gate dielectric layer 56 may be deposited (or grown) in the p-MOS recess 46 and the n-MOS recess 52 above the strained Si layer 54. In the various embodiments, the gate dielectric layer 56 may include silicon dioxide, although other dielectric materials may also be used. A polysilicon deposition may be employed to deposit polysilicon into the p-MOS recess 46 and the n-MOS recess 52, to form a p-MOS gate 58 and an n-MOS gate 60, respectively. The device 10 may then be planarized using a chemical-mechanical planarization (CMP) to remove excess portions of the polysilicon deposition.

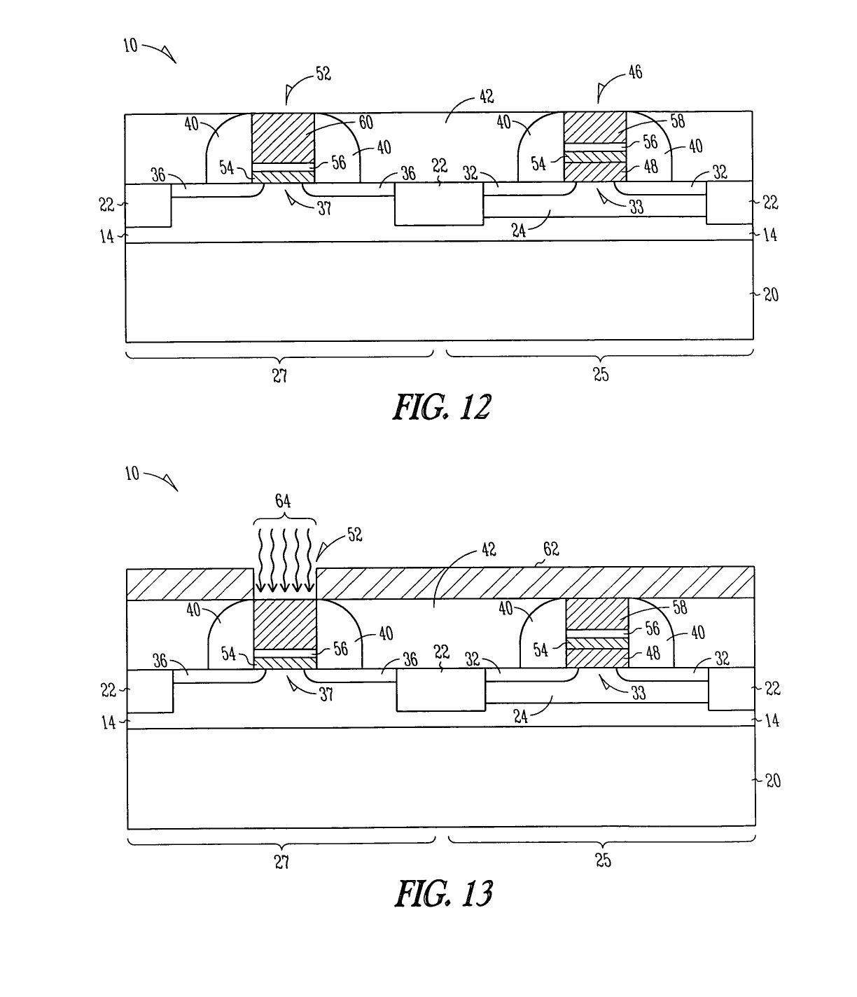

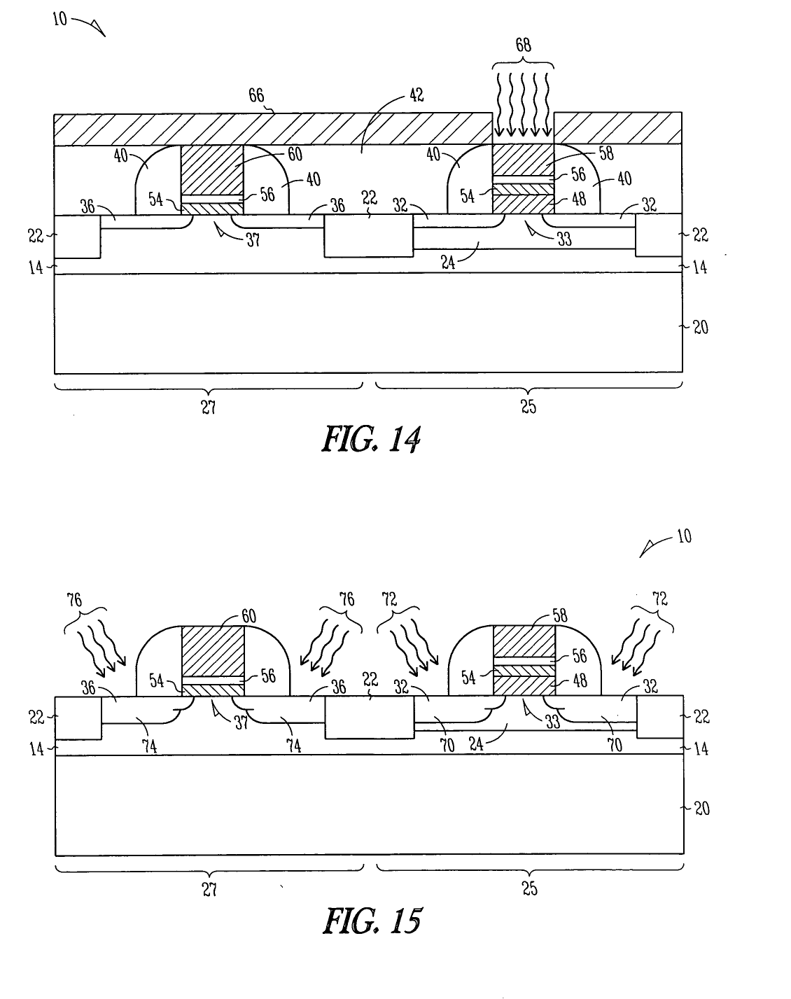

In FIG. 13, the p-MOS region 25 may be masked with a photoresist layer 62 that is patterned to produce an opening adjacent to the n-MOS gate 60. The n-MOS gate 60 may then be implanted with a suitable chemical species by exposing the n-MOS gate 60 to an ion-beam 64 through the opening to adjust a gate threshold voltage of the n-MOS gate 60. The photoresist layer 62 may then be stripped from the device 10.

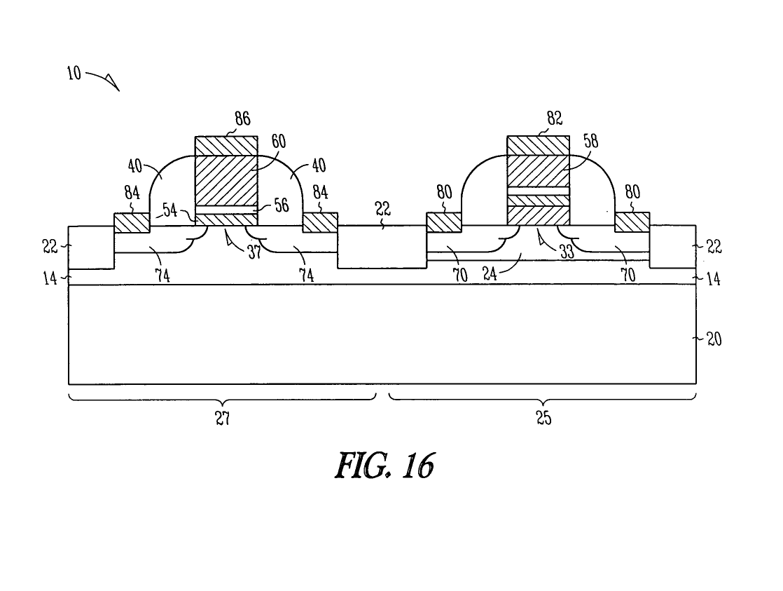

Referring now also to FIG. 14, the n-MOS region 27 may be masked with a photoresist layer 66 that is patterned to produce an opening adjacent to the p-MOS gate 58. The p-MOS gate 58 may then be implanted with a suitable chemical species by exposing the p-MOS gate 58 to an ion-beam 68 through the opening to adjust a gate threshold voltage of the p-MOS gate 58. Following the implantation of the n-MOS gate 60 and the p-MOS gate 58, the device 10 may be subjected to an annealing process, in order to reduce any damage to the n-MOS gate 60 and the p-MOS gate 58 that is caused by the implantation process.

Referring now to FIG. 15, the conformal dielectric layer 42 (shown in FIG. 14) may be removed from the device 10 by etching the layer 42 using a wet or a dry etching process. Source/drain regions 70 may then be formed in the p-MOS region 25 by implanting a suitable chemical species by directing an ion beam 72 into the source/drain extensions 32. Similarly, source/drain regions 74 may be formed in the n-MOS region 27 by implanting a suitable chemical species by directing an ion beam 76 into the source/drain extensions 36. Following the implantations in the p-MOS region 25 and the n-MOS region 27, the source/drain regions 70, and the source/drain regions 74 may be laser annealed in order to concentrate the heating effect of the beam on the source/drain regions 70, and the source/drain regions 74. Accordingly, dopant deactivation in the p-MOS gate 58 and the n-MOS gate 60 may be advantageously avoided.

Turning now to FIG. 16, source/drain electrical contacts 80 may be formed in the p-MOS region 25 to provide electrical coupling between source/drain regions 70 and other circuits that are external to the device 10. A gate electrical contact 82 may also be formed on the p-MOS gate 58. Correspondingly, source/drain electrical contacts 84 may be formed in the n-MOS region 27 to provide electrical coupling between source/drain regions 74 and other circuits that are external to the device 10. A gate electrical contact 86 may also be formed on the n-MOS gate 60. The contact 82 and the contact 86 may be formed on the p-MOS gate 58 and the n-MOS gate 60, respectively, by depositing a suitable metal on the p-MOS gate 58 and the n-MOS gate 60.

Although the various embodiments possess numerous advantages over the prior art, one skilled in the art will readily recognize that the source/drain regions 70 in the pMOS region 25 and the pMOS gate 58 in the pMOS region 25 may be separately implanted so that the implantation may be selectively tailored in the pMOS region 25. Similarly, the source/drain regions 74 in the nMOS region 27 and the nMOS gate 60 in the nMOS region 27 may be separately implanted so that the implantation may also be selectively tailored in the nMOS region 27. Alternately, the source/drain regions 70 and the pMOS gate 58, as well as the source/drain regions 74 and the nMOS gate 60 may be implanted simultaneously.

In some embodiments, the electrical contact 82 and the electrical contact 86 may be formed using a metal silicide. For example, the metal silicide may be a refractory metal silicide corresponding to the formula MSiₓ, where M is a suitable refractory metal, such as tungsten (W), titanium (Ti), molybdenum (Mo) and tantalum (Ta). In either case, the metal silicide may be deposited on the device 10 by sputter-depositing the silicide onto selected portions of the device. Alternately, the silicide may be formed by other methods. For example, the silicide may be formed by depositing a metal directly onto the selected portions so that the deposited metal forms an alloy with silicon. In some cases, the silicide may be formed using chemical vapor deposition (CVD). The source/drain contacts 80 and the source/drain contacts 84 may also be formed on the source/drain regions 70 and the source/drain regions 74, respectively, by depositing a suitable metal on the source/drain regions 70 and the source/drain regions 74. In some embodiments, the source/drain contacts 80 and the source/drain contacts 84 may be formed using a metal silicide, which may include a refractory metal silicide.

FIG. 17 is a partial cross sectional view that will be used to describe a method of forming a semiconductor device 100 according to the various embodiments of the invention. Some of the details illustrated in FIGS. 17 through 25 have been previously discussed. Accordingly, in the interest of brevity, these details may not be described further. Shallow trench isolation (STI) structures 102 may be formed in a SiGe layer 104 that has been previously formed on a substrate 106. The SiGe layer 104 may be formed as previously described, and is comprised according to the general formula Si₁₋ₓGeₓ, where x ranges between approximately 0.5 and 0.6. The STI structures 102 may be formed by applying known photolithographic procedures, which may include applying a photoresist material (not shown in FIG. 17) to an upper surface of the SiGe layer 104, and exposing the photoresist through a suitable mask. The exposed photoresist may be developed to establish openings through the photoresist material at selected locations for the STI structures 102. The selected locations may then be etched to form trenches extending into the SiGe layer 104 using a suitable anisotropic etching process. The trenches thus formed may be filled with a deposited dielectric material to form the STI structures 102. An n-doped well 108 may be formed in the SiGe layer 104 so that a p-MOS region 110 is defined in the semiconductor device 100. An adjacent n-MOS region 112 is also defined in the device 100. The n-doped well 108 may be formed using known doping methods, such as ion implantation, or other suitable methods. Prior to the implantation process, however, a suitable layer (also not shown in FIG. 17) may be applied to the device 100 that is patterned to provide an opening at the desired well location. One suitable layer is a silicon nitride layer that may be stripped from the device 100 following the doping procedure. An annealing process may also be optionally applied to the device 100 following the ion implantation procedure. A pad dielectric layer 114 may then be applied to the device 100. The pad dielectric layer 114 may include, for example, an oxide layer.

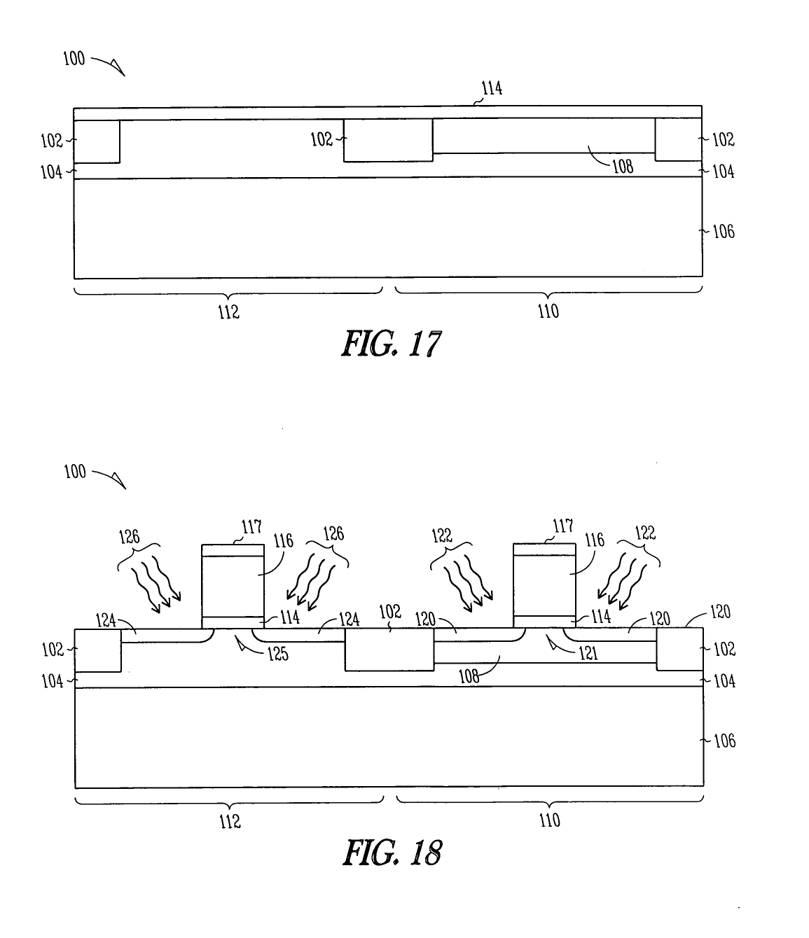

Referring now to FIG. 18, a pair of dummy gate structures 116 may be formed on the device 100 by depositing a polysilicon layer (not shown in FIG. 18) to a desired thickness on the pad dielectric layer 114. A dielectric layer 117 may then be grown or deposited on the polysilicon layer. The polysilicon layer may then be suitably patterned using known photolithographic procedures, as previously described, and selectively removed to form the dummy gate structures 116 in the respective p-MOS region 110 and the n-MOS region 112. In the various embodiments, the dummy gate structures 116 may be formed by reactive ion etching (RIE) the polysilicon layer, although other suitable methods may also be used. The pad dielectric layer 114 may also be stripped from the device 100 so that the remaining portions of the pad dielectric layer 114 are positioned between the dummy gate structures 116 and a surface 118 of the device 100. Source/drain extensions 120 may then be formed in the n-doped well 108 by directing an angled ion implantation 122 of a selected chemical species into the well 108, thus forming a channel region between the source/drain extensions 120. The source/drain extensions 120 may also include halo implantation regions, as previously discussed. Likewise, source/drain extensions 124 may also be formed in the n-MOS region 112 by directing an angled ion implantation 126 of a selected chemical species, so that a channel region 125 is formed between the source/drain extensions 124. The source/drain extensions 124 may also include halo implantation regions.

In FIG. 19, source/drain regions 128 may be formed in the p-MOS region 110 by implanting a suitable chemical species into the source/drain extensions 120 (FIG. 18). Similarly, source/drain regions 130 may be formed in the n-MOS region 112 by implanting a suitable chemical species into the source/drain extensions 124 (also shown in FIG. 18). Insulating spacers 132 may then be formed on opposing sidewalls of each of the dummy gate structures 116 by selective material deposition and etching processes, which are known in the art. Although the insulating spacers 132 may be formed from any dielectric material, in at least one of the various embodiments, the insulating spacers 132 may comprise a nitride, an oxynitride, or any suitable combination of the foregoing dielectric materials.

Still referring to FIG. 19, source/drain electrical contacts 134 may be formed in the p-MOS region 110 to provide electrical coupling between source/drain regions 128 and other circuits that are external to the device 100. Correspondingly, source/drain electrical contacts 136 may be formed in the n-MOS region 112 to provide electrical coupling between source/drain regions 130 and other circuits that are external to the device 100. Although the source/drain electrical contacts 134 and the source/drain electrical contacts 136 may be formed using any conductive material, in the various embodiments, the source/drain electrical contacts 134 and the source/drain electrical contacts 136 may include a metal silicide. For example, the metal silicide may be a refractory metal silicide corresponding to the formula MSiₓ, where M is a suitable refractory metal, such as tungsten (W), titanium (Ti), molybdenum (Mo) and tantalum (Ta).

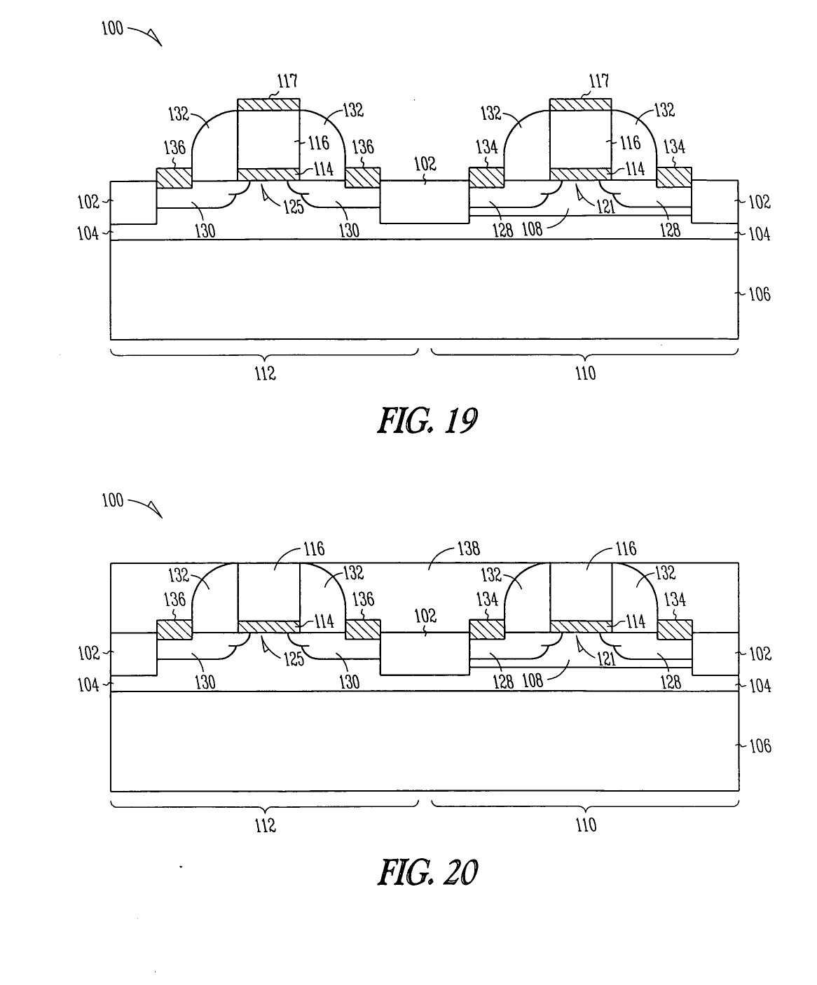

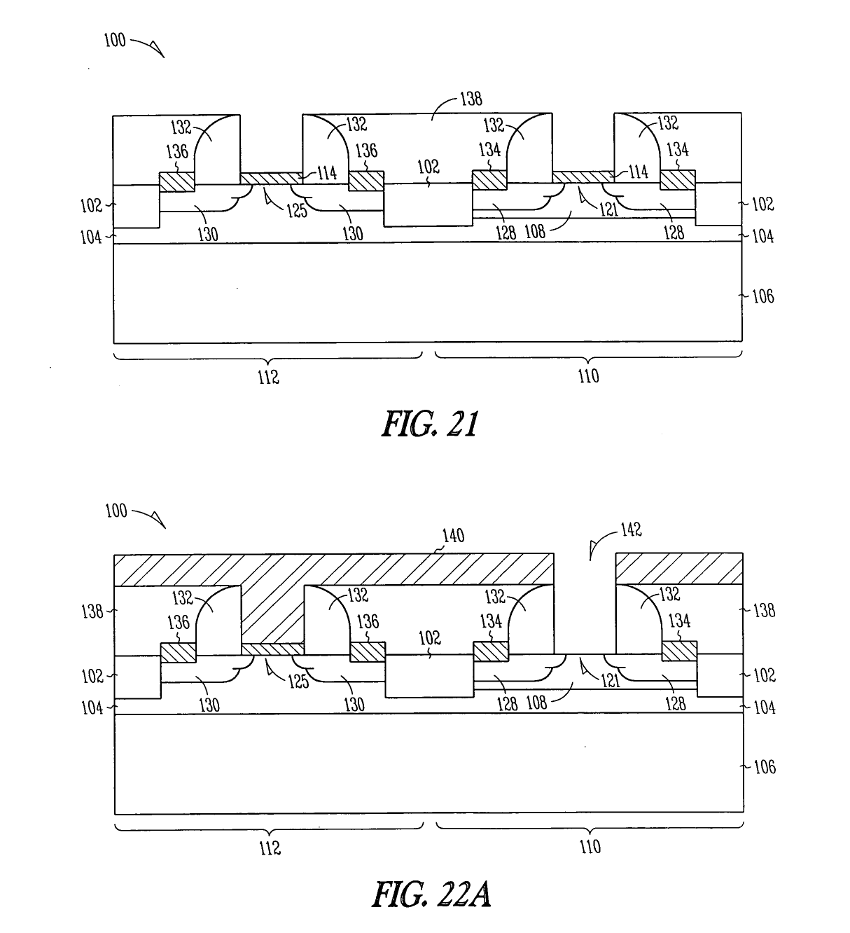

As shown in FIG. 20, a conformal dielectric layer 138 may be applied to the device 100 that substantially covers the surface 118 and that further encloses the dummy gate structures 116 and the insulating spacers 132. The conformal dielectric layer 138 may include, for example, a silicon dioxide layer that is deposited on the device 100 using chemical vapor deposition (CVD), but in the various embodiments, the layer 138 may be formed by the pyrolysis of tetraethylorthosilicate (TEOS). Following deposition of the conformal dielectric layer 138, planarization using chemical-mechanical planarization (CMP) may be performed on the device 100 so that a thickness of the layer 138 extends from the surface 118 to approximately a height of the dummy gate structures 116. An endpointing layer may be optionally included in the layer 138 so that the planarization may be stopped when the dummy gate structures 116 are exposed.

In FIG. 21, the dummy gate structures 116 for the p-MOS region 110 and the n-MOS region 112 may be selectively removed from the device 100, so that the pad dielectric layer 114 in the p-MOS region 110 and the n-MOS region 112 are exposed. The dummy gate structures 116 may be selectively removed by any suitable etch procedure that is relatively selective for polysilicon. For example, the dummy gate structures 116 may be removed using a dry etch process, such as plasma etching that employs a suitable chemistry, although other dry etch methods may also be used.

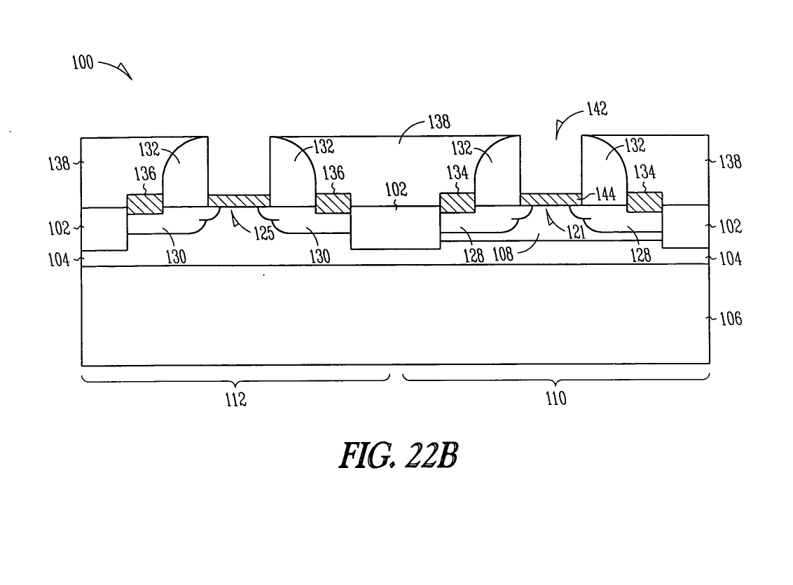

Turning now to FIG. 22a, a photoresist layer 140 may be applied to an exposed surface of the conformal dielectric layer 138, which may be removed from the p-MOS region 110 by photolithographic methods, so that a p-MOS recess 142 is defined. The pad dielectric layer 114 may then be removed from the p-MOS recess 142. The photoresist layer 140 may then be stripped from the conformal dielectric layer 138. A strained germanium (Ge) layer 144 may then be grown in the p-MOS recess 142, as shown in FIG. 22b. In some embodiments, the strained Ge layer 144 may be epitaxially grown to a thickness of approximately 12 nanometers (nm), although the strained Ge layer 144 may have other suitable thicknesses, which may be greater than, or even less than approximately 12 nm.

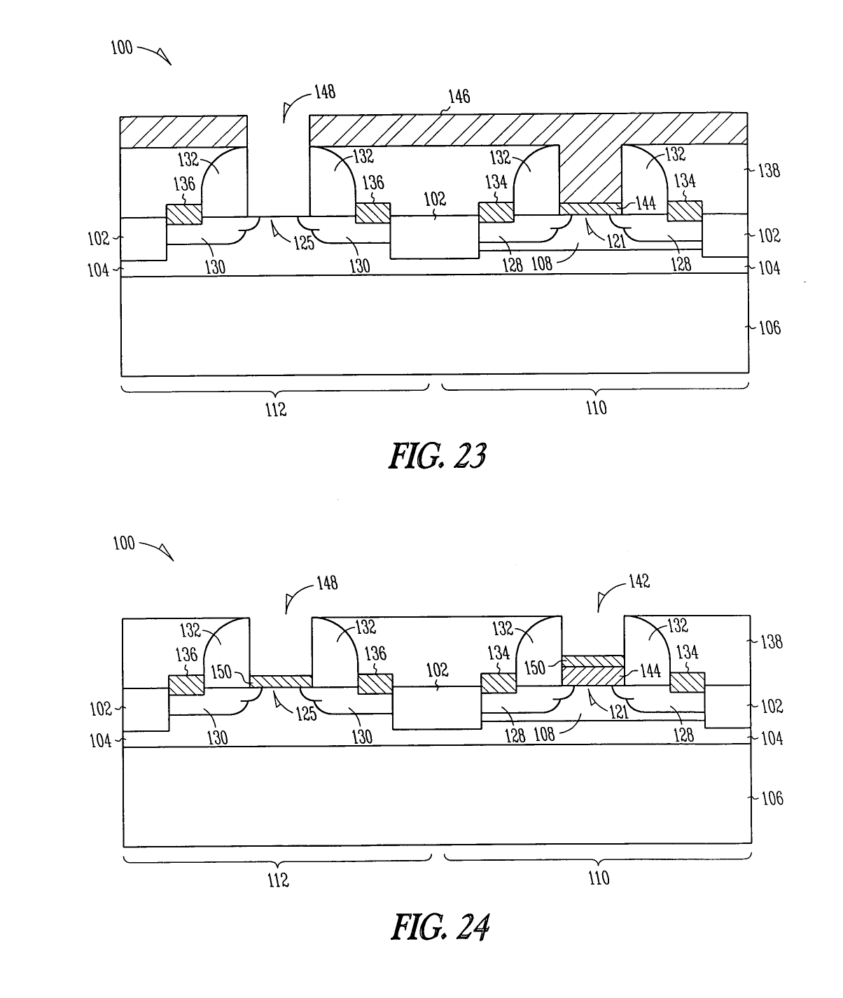

In FIG. 23, a photoresist layer 146 may be applied to the exposed surface of the conformal dielectric layer 138, which may be locally removed from the n-MOS region 112 to define an n-MOS recess 148. The pad dielectric layer 114 may then be removed from the n-MOS recess 148. With reference also now to FIG. 24, the photoresist layer 146 may then be stripped to expose the p-MOS recess 142. A strained silicon (Si) layer 150 may then be grown in the p-MOS recess 142 and the n-MOS recess 148. In the various embodiments, the strained Si layer 150 may be epitaxially grown to a thickness of approximately five nanometers (nm), although the strained Si layer 150 may have other thicknesses, which may be greater or even less than this thickness.

FIG. 25 shows a dielectric film 152 applied to the device 100 that extends downwardly into the p-MOS recess 142 and the n-MOS recess 148 to form a gate dielectric. The dielectric film 152 may comprise a material having a high dielectric constant (a “high-k dielectric” material). For example, selected oxides and silicates of zirconium (Zr) and hafnium (Hf) may be used. Other suitable materials may include, for example, Al₂O₃, Gd₂O₃, Yb₂O₃, Dy₂O₃, Nb₂O₅, Y₂O₃, La₂O₃, TiO₂, Ta₂O₅, SrTiO₃, BaₓSr₁₋ₓTiO₃, ZrₓSi₁₋ₓO_{y}, HfₓSi₁₋ₓO_{y} and AlₓZr₁₋ₓO₂, as well as other compounds. A first metallization 154 may be deposited into the p-MOS recess 142 to form a gate structure for the p-MOS region 110. Correspondingly, a second metallization 156 may be deposited into the n-MOS recess 148 to form a gate structure for the p-MOS region 110. The first metallization 154 and the second metallization 156 may be formed, for example, by vacuum evaporation, and by sputtering methods known in the art. The materials used for the first metallization 154 and the second metallization 156 may include aluminum (Al), gold (Au) and various refractory metals.

Although the various embodiments possess numerous advantages over the prior art, still other advantages will be readily appreciated by those skilled in the art. For example, it will be appreciated that high temperature processes are eliminated in many of the foregoing process steps, so that subsequent process steps may include relatively low temperature processes, such as silicide deposition processes, or other similar low temperature processes.

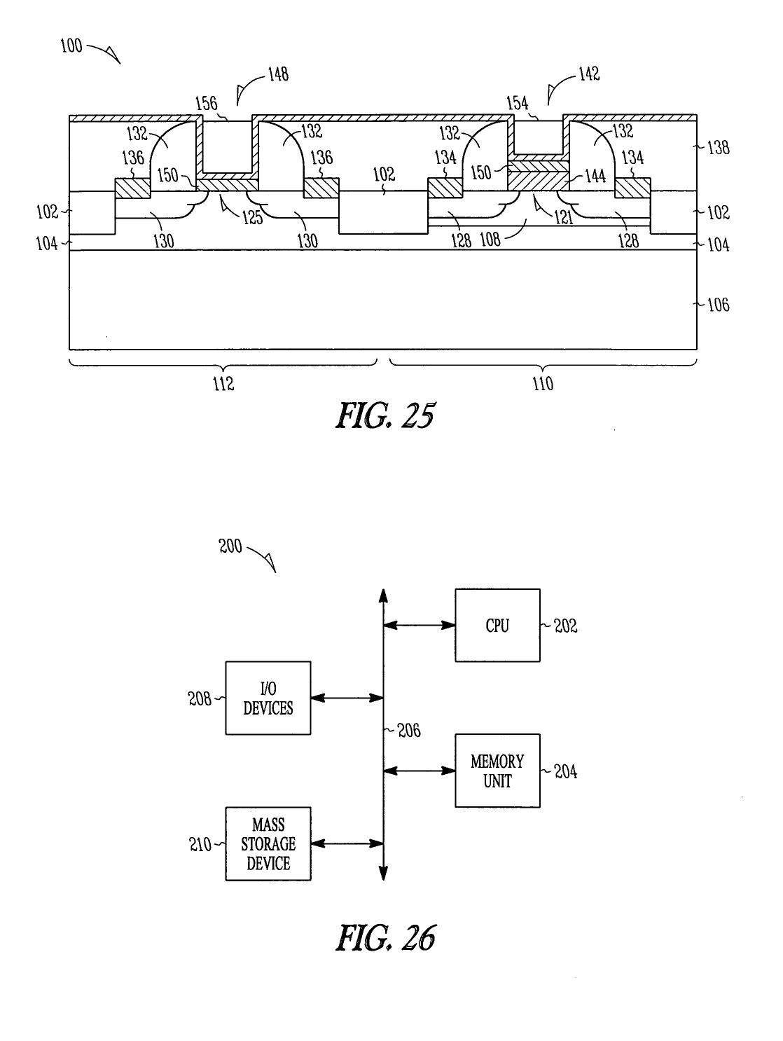

FIG. 26 is a diagrammatic block view of a processing system 200 according to the several embodiments of the invention. The processing system 200 includes a central processing unit (CPU) 202, which may include any digital device capable of receiving data and programmed instructions that is further configured to process the data according to the programmed instructions. Accordingly, the CPU 202 may include a microprocessor, such as a general purpose single-chip or multi-chip microprocessor, or it may include a digital signal processing unit, or other similar programmable processing units. The CPU 202 may be configured to communicate with a memory unit 204 over a communications bus 206. The memory unit 204 may include enhanced mobility MOSFET devices according to the various embodiments of the invention. Additionally, the CPU 202 may also include enhanced mobility MOSFET devices according to the various embodiments. The processing system 200 may also include various other devices that are coupled to the bus 206, which are operable to cooperatively interact with the CPU 202 and the memory unit 204. For example, the processing system 200 may include one or more input/output (I/O) devices 208, such as a printer, a display device, a keyboard, a mouse, or other known input/output devices. The processing system 200 may also include a mass storage device 210, which may include a hard disk drive, a floppy disk drive, an optical disk device (CD-ROM), or other similar devices.

While the various embodiments of the invention have been illustrated and described, as noted above, many changes can be made without departing from the scope of this disclosure. For example, although several embodiments of the isolation region may include memory devices, it is understood that the foregoing embodiments may also be used in a wide variety of other semiconductor devices. For example, the several embodiments may include various digital and analog devices, which may include various logic and memory circuits. With respect to memory circuits in particular, the foregoing embodiments may be incorporated, without significant modification, to a static memory, a dynamic memory such as a dynamic random access memory (DRAM), an extended data out (EDO) DRAM, a double data rate synchronous DRAM (DDR SDRAM), a synchronous link DRAM (SLDRAM), a video random access memory (VRAM), a RAMBUS DRAM (RDRAM), a static random access memory (SRAM), a flash memory, as well as other memory devices.

The accompanying drawings that form a part hereof show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features may be grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment.

What is claimed is:

1. A method of forming a semiconductor device, comprising:
providing a layer of a semiconductor material on a supporting substrate;
forming isolation structures within the semiconductor material to define a first device region and a second device region that is spaced apart from the first device region;
altering a conductivity of the semiconductor material within the second device region to form a well having a selected conductivity;
disposing a layer of a first strained semiconductor material on a surface of the well, and a layer of a second strained semiconductor material on a surface of the first device region;
providing a layer of the second strained semiconductor material on the first strained semiconductor material disposed on the surface of the well;
forming source/drain regions in the well and in the first device region;
disposing a dielectric layer on the second strained semiconductor material; and
positioning gate structures on the dielectric layer.

2. The method of claim 1, wherein providing a layer of a semiconductor material on a supporting substrate further comprises forming a layer comprised of a selected combination of semiconductor materials.

3. The method of claim 2, wherein forming a layer comprised of a selected combination of semiconductor materials further comprises forming a layer comprised of silicon (Si) and germanium (Ge).

4. The method of claim 3, wherein forming a layer comprised of silicon (Si) and germanium (Ge) further comprises forming the layer comprising components selected according to the general formula Si₁₋ₓGeₓ, wherein x is a selected fractional value of one.

5. The method of claim 4, further comprising selecting a value of x ranging between approximately 0.5 and 0.6.

6. The method of claim 1, wherein forming isolation structures within the semiconductor material further comprises forming shallow trench isolation structures that include silicon dioxide.

7. The method of claim 1, wherein altering a conductivity of the semiconductor material within the second device region to form a well further comprises doping the second device region to form a well having an n-type conductivity.

8. The method of claim 1, wherein disposing a layer of a first strained semiconductor material on a surface of the well, and a layer of a second strained semiconductor material on a surface of the first device region further comprises applying a layer of strained germanium (Ge) on the surface of the well, and applying a layer of strained silicon (Si) on the surface of the first device region.

9. The method of claim 8, wherein applying a layer of strained germanium (Ge) on the surface of the well further comprises forming the layer to have a thickness of approximately 12 nanometers (nm).

10. The method of claim 8, wherein applying a layer of strained silicon (Si) on the surface of the first device region further comprises forming the layer of strained Si to have a thickness of approximately five nanometers (nm).

11. The method of claim 1, wherein providing a layer of the second strained semiconductor material on the first strained semiconductor material disposed on the surface of the well further comprises applying a layer of strained silicon (Si) on a layer of strained germanium (Ge).

12. The method of claim 11, wherein applying a layer of strained silicon (Si) on a layer of strained germanium (Ge) further comprises forming the strained silicon (Si) to have a thickness of approximately five nanometers (nm), and forming the strained germanium (Ge) to have a thickness of approximately 12 nanometers (nm).

13. The method of claim 1, wherein forming source/drain regions in the well and in the first device region further comprises:
providing source/drain extensions by implanting a selected chemical species; and
forming a halo implantation region adjacent to the source/drain extensions.

14. The method of claim 1, wherein disposing a dielectric layer on the second strained semiconductor material further comprises disposing one of a silicon dioxide layer and a silicon nitride layer.

15. The method of claim 1, wherein disposing a dielectric layer on the second strained semiconductor material further comprises disposing a selected oxide of hafnium (Hf) and zirconium (Zr) on the second strained semiconductor material.

16. The method of claim 1, wherein disposing a dielectric layer on the second strained semiconductor material further comprises disposing a selected silicate of hafnium (Hf) and zirconium (Zr) on the second strained semiconductor material.

17. The method of claim 1, wherein positioning a gate structure on the dielectric layer further comprises positioning a polysilicon gate structure on the dielectric layer.

18. The method of claim 1, wherein positioning gate structures on the dielectric layer further comprises positioning one of a metal and a silicide on the dielectric layer.

19. The method of claim 1, further comprising forming source/drain electrical contacts in the source/drain regions, and forming gate electrical contacts on the gate structures.

20. The method of claim 19, wherein forming source/drain electrical contacts in the source/drain regions, and forming gate electrical contacts on the gate structures further comprises forming one of a metal and a silicide structure in the source/drain regions and the gate structures.

21. A method of forming a semiconductor device, comprising:
processing a substrate to provide a layer of a selected semiconductor material on the substrate;
providing a first device region and a second device region in the layer of a selected semiconductor material by interposing an isolation structure between the first device region and the second device region;
providing source/drain regions in the first device region;
forming a well in the second device region having a selected conductivity and providing source/drain regions in the well;
forming a layer of a first strained semiconductor material on a surface of the well, and a layer of a second strained semiconductor material on a surface of the first device region;
forming a layer of the second strained semiconductor material on the first strained semiconductor material disposed on the surface of the well;
providing a dielectric layer on the second strained semiconductor material; and
forming gate structures on the dielectric layer.

22. The method of claim 21, wherein processing a substrate further comprises providing one of a bulk silicon substrate and a silicon-on-insulator structure.

23. The method of claim 21, wherein processing a substrate further comprises:
forming a surface layer of the selected semiconductor material on a first substrate;
bonding the surface layer of the selected semiconductor material to a second substrate; and
removing the first substrate to expose the layer of the selected semiconductor material on the second substrate.

24. The method of claim 23, wherein forming a surface layer of the selected semiconductor material further comprises thermally growing the selected semiconductor material on the first substrate; and wherein removing the first substrate further comprises grinding the first substrate and at least a portion of the selected semiconductor material.

25. The method of claim 21, wherein processing a substrate further comprises forming a layer comprised of silicon (Si) and germanium (Ge) on the substrate.

26. The method of claim 25, wherein forming a layer comprised of silicon (Si) and germanium (Ge) further comprises selecting components according to the general formula Si₁₋ₓGeₓ, wherein x is a selected value ranging between approximately 0.5 and 0.6.

27. The method of claim 21, wherein interposing an isolation structure between the first device region and the second device region further comprises forming shallow trench isolation structures that include silicon dioxide.

28. The method of claim 21, wherein forming a well in the second device region further comprises doping the second device region to form a well having an n-type conductivity.

29. The method of claim 21, wherein forming a layer of a first strained semiconductor material on a surface of the well, and a layer of a second strained semiconductor material on a surface of the first device region further comprises forming a layer of strained germanium (Ge) on the surface of the well, and forming a layer of strained silicon (Si) on the surface of the first device region.

30. The method of claim 29, wherein forming a layer of strained germanium (Ge) on the surface of the well further comprises forming the layer to have a thickness of approximately 12 nanometers (nm).

31. The method of claim 29, wherein forming a layer of strained silicon (Si) on the surface of the first device region further comprises forming the layer to have a thickness of approximately five nanometers (nm).

32. The method of claim 21, wherein forming a layer of the second strained semiconductor material on the first strained semiconductor material disposed on the surface of the well further comprises applying a layer of strained silicon (Si) on a layer of strained germanium (Ge).

33. The method of claim 32, wherein forming a layer of strained silicon (Si) on a layer of strained germanium (Ge) further comprises forming the strained silicon (Si) to have a thickness of approximately five nanometers (nm), and forming the strained germanium (Ge) to have a thickness of approximately 12 nanometers (nm).

34. The method of claim 21, wherein providing a dielectric layer on the second strained semiconductor material further comprises forming a silicon dioxide layer.

35. The method of claim 21, wherein providing a dielectric layer on the second strained semiconductor material further comprises forming a selected oxide of hafnium (Hf) and zirconium (Zr) on the second strained semiconductor material.

36. The method of claim 21, wherein providing a dielectric layer on the second strained semiconductor material further comprises disposing a selected silicate of hafnium (Hf) and zirconium (Zr) on the second strained semiconductor material.

37. The method of claim 21, wherein forming gate structures on the dielectric layer further comprises forming a polysilicon gate structure on the dielectric layer.

38. The method of claim 21, wherein forming gate structures on the dielectric layer further comprises positioning one of a metal and a silicide on the dielectric layer.

39. The method of claim 21, further comprising positioning source/drain electrical contacts on the source/drain regions, and positioning gate electrical contacts on the gate structures.

40. The method of claim 39, wherein positioning source/drain electrical contacts in the source/drain regions, and positioning gate electrical contacts on the gate structures further comprises forming one of a metal and a silicide structure on the source/drain regions and on the gate structures.

41. A method, comprising:
providing a substrate having a layer of a selected semiconductor material disposed on the substrate;
isolating a first portion of the selected semiconductor material from a second portion of the selected semiconductor material by interposing an isolation structure between the first portion and the second portion;
providing a pair of spaced apart source/drain regions in the first portion and a first channel region therebetween;
forming a well in the second portion having a selected conductivity that is different from a conductivity of the first channel region;
providing a pair of spaced apart source/drain regions in the well and a second channel region therebetween;
forming a layer of a first strained semiconductor material on the second channel region and a layer of a second strained semiconductor material on the first channel region;
forming a layer of the second strained semiconductor material on the first strained semiconductor material formed on the second channel region;
applying a dielectric layer on the second strained semiconductor material; and
forming gate structures on the dielectric layer.

42. The method of claim 41, wherein providing a substrate having a layer of a selected semiconductor material further comprises selecting one of a bulk silicon structure and a silicon-on-insulator structure.

43. The method of claim 42, wherein providing a substrate having a layer of a selected semiconductor material further comprises thermally growing a layer comprised of silicon (Si) and germanium (Ge) on the selected structure.

44. The method of claim 43, wherein thermally growing a layer comprised of silicon (Si) and germanium (Ge) further comprises thermally growing a layer having components selected according to the general formula Si₁₋ₓGeₓ, wherein x is a selected value that ranges between approximately 0.5 and 0.6.

45. The method of claim 41, wherein isolating a first portion of the selected semiconductor material from a second portion of the selected semiconductor material further comprises forming shallow trench isolation structures that are substantially filled with silicon dioxide.

46. The method of claim 41, wherein forming a well in the second portion having a selected conductivity further comprises implanting the second portion with a selected species to form a well having an n-type conductivity.

47. The method of claim 41, wherein forming a layer of a first strained semiconductor material on the second channel region and a layer of a second strained semiconductor material on the first channel region further comprises forming a layer of strained silicon (Si) on the first channel region and forming a layer of strained germanium (Ge) on the second channel region.

48. The method of claim 47, wherein forming a layer of strained silicon (Si) on the first channel region further comprises depositing a layer of strained silicon (Si) having a thickness of approximately five nanometers (nm).

49. The method of claim 47, wherein forming a layer of strained germanium (Ge) on the second channel region further comprises depositing a layer of strained germanium (Ge) having a thickness of approximately 12 nanometers (nm).

50. The method of claim 41, wherein forming a layer of the second strained semiconductor material on the first strained semiconductor material formed on the second channel region further comprises depositing a layer of strained silicon (Si) having a thickness of approximately five nanometers (nm).

51. The method of claim 41, wherein applying a dielectric layer on the first strained semiconductor material further comprises depositing a silicon dioxide layer onto the first strained semiconductor material.

52. The method of claim 41, wherein applying a dielectric layer on the first strained semiconductor material further comprises depositing a high-k dielectric material onto the first strained semiconductor material.

53. The method of claim 52, wherein depositing a high-k dielectric material onto the first strained semiconductor material further comprises applying a selected silicate of hafnium (Hf) and zirconium (Zr) onto the first strained semiconductor material.

54. The method of claim 41, wherein forming gate structures on the dielectric layer further comprises depositing a polysilicon structure on the dielectric layer.

55. The method of claim 41, wherein forming gate structures on the dielectric layer further comprises depositing one of a metal and a metal silicide on the dielectric layer.

56. The method of claim 41, further comprising forming source/drain electrical contacts on the source/drain regions, and forming electrical contacts on the gate structures.

57. A semiconductor device, comprising:
a layer of a semiconductor material disposed on a supporting substrate;
at least one isolation structure positioned within the semiconductor material to define a first device region and a second device region that is spaced apart from the first device region;
a well having a selected conductivity formed in the second device region;
a layer of a first strained semiconductor material disposed on a surface of the well, and a layer of a second strained semiconductor material disposed on a surface of the first device region;
a layer of the second strained semiconductor material disposed on the first strained semiconductor material on the surface of the well;
source/drain regions formed in the well and in the first device region;
a dielectric layer disposed on the second strained semiconductor material; and
gate structures positioned on the dielectric layer.

58. The semiconductor device of claim 57, wherein the layer of a semiconductor material disposed on a supporting substrate further comprises a layer that includes a selected combination of silicon (Si) and germanium (Ge).

59. The semiconductor device of claim 58, wherein the layer that includes a selected combination of silicon (Si) and germanium (Ge) further comprises a layer having components selected according to the general formula Si₁₋ₓGeₓ, wherein x ranges between approximately 0.5 and approximately 0.6.

60. The semiconductor device of claim 57, wherein the at least one isolation structure further comprises at least one shallow trench isolation structure that is substantially filled with silicon dioxide.

61. The semiconductor device of claim 57, wherein the well having a selected conductivity formed in the second device region further comprises a well having an n-type conductivity.

62. The semiconductor device of claim 57, wherein the layer of a first strained semiconductor material on the surface of the well, and a layer of a second strained semiconductor material disposed on a surface of the first device region further comprises a layer of strained germanium (Ge) disposed on the surface of the well, and a layer of strained silicon (Si) disposed on the surface of the first device region.

63. The semiconductor device of claim 62, wherein the layer of strained germanium (Ge) on the surface of the well further comprises a strained germanium (Ge) layer having a thickness of approximately 12 nanometers (nm).

64. The semiconductor device of claim 62, wherein the layer of strained silicon (Si) on the surface of the first device region further comprises a strained silicon (Si) layer having a thickness of approximately five nanometers (nm).

65. The semiconductor device of claim 57, wherein the layer of the second strained semiconductor material disposed on the first strained semiconductor material further comprises a layer of strained silicon (Si) disposed on a layer of strained germanium (Ge).

66. The semiconductor device of claim 57, wherein the dielectric layer disposed on the second strained semiconductor material further comprises one of a silicon dioxide layer and a silicon nitride layer.

67. The semiconductor device of claim 57, wherein the dielectric layer disposed on the second strained semiconductor material further comprises a high-k dielectric material that includes a selected oxide of hafnium (Hf) and zirconium (Zr) on the second strained semiconductor material.

68. The semiconductor device of claim 57, wherein the dielectric layer disposed on the second strained semiconductor material further comprises a high-k dielectric material that includes a selected silicate of hafnium (Hf) and zirconium (Zr) on the second strained semiconductor material.

69. The semiconductor device of claim 57, wherein the gate structures positioned on the dielectric layer further comprise polysilicon gate structures positioned on the dielectric layer.

70. The semiconductor device of claim 57, wherein the gate structures positioned on the dielectric layer further comprise one of a metal and a silicide positioned on the dielectric layer.

71. The semiconductor device of claim 57, further comprising source/drain electrical contacts formed in the source/drain regions, and gate electrical contacts formed on the gate structures.

72. The semiconductor device of claim 71, wherein the source/drain electrical contacts in the source/drain regions, and forming gate electrical contacts on the gate structures further comprises forming one of a metal and a silicide structure in the source/drain regions and the gate structures.

73. A processing system, comprising:
a central processing unit (CPU); and
a memory device operably coupled to the CPU by a communications bus,
at least one of the memory device and the CPU including a semiconductor device further comprising:
a layer of a semiconductor material disposed on a supporting substrate;
at least one isolation structure positioned within the semiconductor material to define a first device region and a second device region that is spaced apart from the first device region;
a well having a selected conductivity formed in the second device region;
a layer of a first strained semiconductor material disposed on a surface of the well, and a layer of a second strained semiconductor material disposed on a surface of the first device region;
a layer of the second strained semiconductor material disposed on the first strained semiconductor material on the surface of the well;
source/drain regions formed in the well and in the first device region;
a dielectric layer disposed on the second strained semiconductor material; and
gate structures positioned on the dielectric layer.

74. The processing system of claim 73, wherein the layer of a semiconductor material disposed on a supporting substrate further comprises a layer that includes a selected combination of silicon (Si) and germanium (Ge).

75. The processing system of claim 74, wherein the layer that includes a selected combination of silicon (Si) and germanium (Ge) further comprises a layer having components selected according to the general formula Si₁₋ₓGeₓ, wherein x ranges between approximately 0.5 and approximately 0.6.

76. The processing system of claim 73, wherein the at least one isolation structure further comprises at least one shallow trench isolation structure that is substantially filled with silicon dioxide.

77. The processing system of claim 73, wherein the well having a selected conductivity formed in the second device region further comprises a well having an n-type conductivity.

78. The processing system of claim 73, wherein the layer of a first strained semiconductor material on the surface of the well, and a layer of a second strained semiconductor material disposed on a surface of the first device region further comprises a layer of strained germanium (Ge) disposed on the surface of the well, and a layer of strained silicon (Si) disposed on the surface of the first device region.

79. The processing system of claim 78, wherein the layer of strained germanium (Ge) on the surface of the well further comprises a strained germanium (Ge) layer having a thickness of approximately 12 nanometers (nm).

80. The processing system of claim 78, wherein the layer of strained silicon (Si) on the surface of the first device region further comprises a strained silicon (Si) layer having a thickness of approximately five nanometers (nm).

81. The processing system of claim 73, wherein the layer of the second strained semiconductor material disposed on the first strained semiconductor material further comprises a layer of strained silicon (Si) disposed on a layer of strained germanium (Ge).

82. The processing system of claim 73, wherein the dielectric layer disposed on the second strained semiconductor material further comprises one of a silicon dioxide layer and a silicon nitride layer.

83. The processing system of claim 73, wherein the dielectric layer disposed on the second strained semiconductor material further comprises a high-k dielectric material that includes a selected oxide of hafnium (Hf) and zirconium (Zr) on the second strained semiconductor material.

84. The processing system of claim 73, wherein the dielectric layer disposed on the second strained semiconductor material further comprises a high-k dielectric material that includes a selected silicate of hafnium (Hf) and zirconium (Zr) on the second strained semiconductor material.

85. The processing system of claim 73, wherein the gate structures positioned on the dielectric layer further comprise polysilicon gate structures positioned on the dielectric layer.

86. The processing system of claim 73, wherein the gate structures positioned on the dielectric layer further comprise one of a metal and a silicide positioned on the dielectric layer.

87. The processing system of claim 73, further comprising source/drain electrical contacts formed in the source/drain regions, and gate electrical contacts formed on the gate structures.

88. The processing system of claim 87, wherein the source/drain electrical contacts in the source/drain regions, and forming gate electrical contacts on the gate structures further comprises forming one of a metal and a silicide structure in the source/drain regions and the gate structures.
